(19) United States
(12) Patent Application Publication
(10) Pub. No.: US 2004/0125000 A1
(43) Pub. Date: Jul. 1, 2004

(54) Low noise keyboard pushbutton structure

(76) Inventor: Yu Long Lee, Shin Juang City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/331,468

(22) Filed: Dec. 31, 2002

(51) Int. Cl. H03M 11/00; H03K 17/94

(52) U.S. Cl. 341/22

(57) ABSTRACT

A keyboard includes a circuit board on which a silo is formed. A pushbutton structure includes a cap from which a post extends. The post is movably received in the silo whereby the cap is movable between a released position and an actuated position. The keyboard includes a resilient cone supporting the post at the released position. When the pushbutton is depressed, the cap moves from the released position to the actuated position where the post deforms the cone to trigger a contact switch of the circuit board and generate a signal indicating the depression. Two resilient slide tabs are formed on opposite sides of the post and each slide tab has an inclined surface for resiliency-biased engagement with an inside surface of the silo to ensure stable and sound movement of the cap with respect to the silo. A stop bar is mounted to the post by two fingers on opposite sides of each slide tab. The stop bar is selectively engageable with an internal shoulder of the silo to retain the cap at the released position. The stop bar and the corresponding slide tab are formed on the same side of the post bar, whereby overall size of the post is reduced and manufacturing costs are lowered.

### BACKGROUND OF THE INVENTION

1. Field of the Invention

The present invention generally relates to a pushbutton structure of a keyboard, and in particular to a low noise keyboard pushbutton structure.

2. The Related Art

A computer keyboard is one of the most commonly used input devices for a computer system. The computer keyboard comprises a number of pushbuttons, each comprising a movable cap having a post extending from a bottom side of the cap. The post is movably received in a guide silo whereby the cap is allowed to move with respect to a circuit board arranged inside the keyboard casing between a released position and an actuated position. When the cap is moved to the actuated position, the post indirectly engages and triggers a contact switch to generate a signal corresponding to the strike of the particular pushbutton.

Due to the miniaturization trend of the computer industry, the pushbutton is made small and compact. This reduces the contact area between the post and the guide silo, which in turn makes the cap easy to jam with the silo. In addition, the small contact area also causes instable movement of the cap along the silo, which in turn gives off undesired noise.

Another disadvantage observed in the conventional keyboard pushbutton structure is that the post and the silo are subject to wearing of different extents due to being struck by people with different striking forces. The worn part induces additional noise during the operation of the keyboard.

Thus, it is desired to have a keyboard pushbutton structure to overcome the noise problems.

### SUMMARY OF THE INVENTION

An object of the present invention is to provide a keyboard pushbutton that generates noise of low level.

Another object of the present invention is to provide a keyboard pushbutton structure that allows for stable movement of the pushbutton during operation thereof.

A further object of the present invention is to provide a low noise keyboard pushbutton having a compact structure for reducing overall costs.

To achieve the above objects, in accordance with the present invention, there is provided a pushbutton structure for a keyboard comprising a circuit board on which a silo is formed. The pushbutton structure comprises a cap from which a post extends. The post is movably received in the silo whereby the cap is movable between a released position and an actuated position. The keyboard comprises a resilient cone supporting the post at the released position. When the pushbutton is depressed, the cap moves from the released position to the actuated position where the post deforms the cone to trigger a contact switch of the circuit board and generate a signal indicating the depression. Two resilient slide tabs are formed on opposite sides of the post and each slide tab has an inclined surface for resiliency-biased engagement with an inside surface of the silo to ensure stable and sound movement of the cap with respect to the silo, which in turn reduces the noise caused by the movement of the cap. A stop bar is mounted to the post by two fingers on opposite sides of each slide tab. The stop bar is selectively engageable with an internal shoulder of the silo to retain the cap at the released position. The stop bar and the corresponding slide tab are formed on the same side of the post bar, whereby overall size of the post is reduced and manufacturing costs are lowered.

### BRIEF DESCRIPTION OF THE DRAWINGS

The present invention will be apparent to those skilled in the art by reading the following description of a preferred embodiment thereof, with reference to the attached drawings, in which:

FIG. 1 is a perspective view of a keyboard pushbutton constructed in accordance with the present invention with a cap detached from a silo of the keyboard;

FIG. 2 is an up-side-down perspective view of the cap of the keyboard pushbutton of the present invention;

FIG. 3 is an enlarged view of the encircled portion of FIG. 2;

FIG. 4 is an exploded view, in section form, of the keyboard pushbutton of the present invention;

FIG. 5 is a cross-sectional view of the keyboard pushbutton of the present invention at a released position; and

FIG. 6 is a cross-sectional view of the keyboard pushbutton at an actuated position.

### DETAILED DESCRIPTION OF THE PREFERRED EMBODIMENT

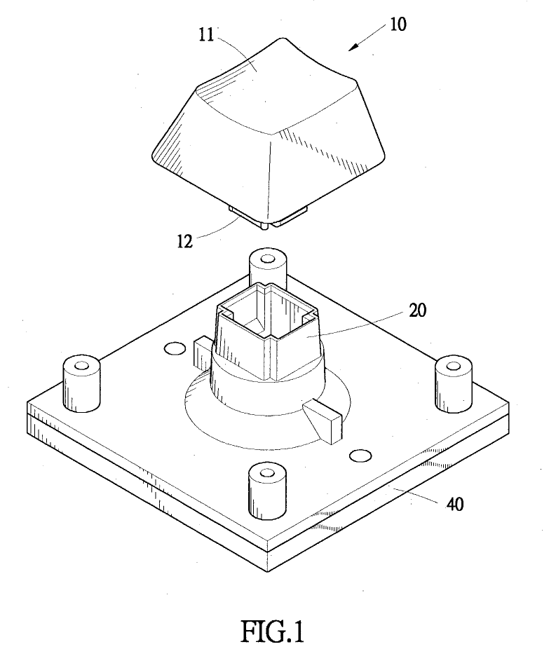

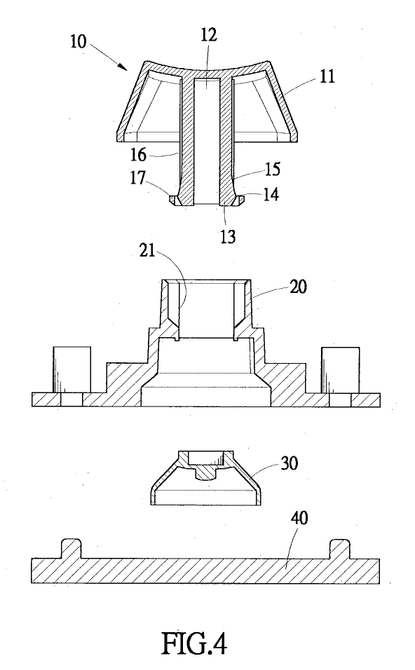

With reference to the drawings and in particular to FIGS. 1 and 4, a keyboard pushbutton constructed in accordance with the present invention, generally designated with reference numeral 10, comprises a cap 11 movably mounted on a silo 20 extending from a circuit board 40 of a keyboard. The cap 11 is supported by a resilient, collapsible cone 30, preferably made of rubber or similar materials, at a released condition. The cap 11 can be depressed to deform the cone 30 for triggering a switch contact formed on the circuit board 40 to generate a signal corresponding to the depression or actuation of the pushbutton 10.

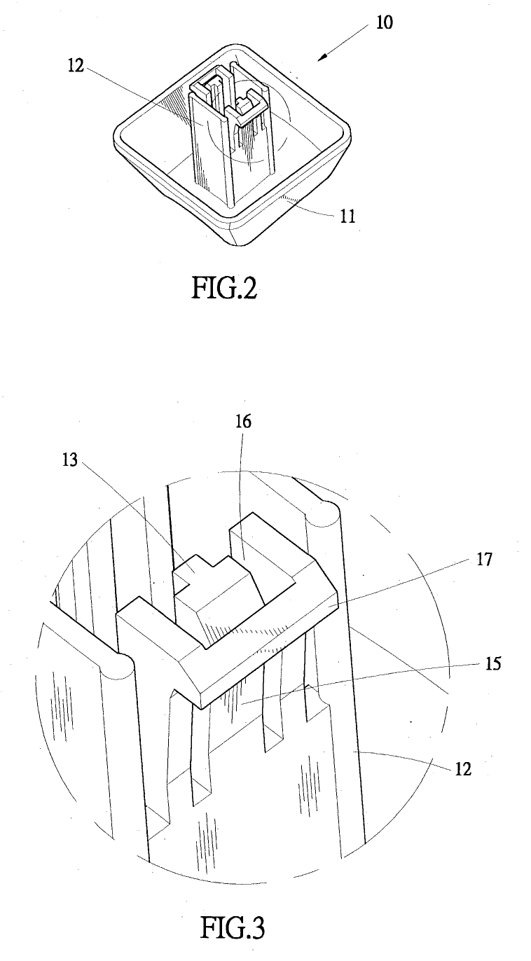

Also referring to FIGS. 2 and 3, the cap 11 comprises a post 12 extending from a bottom side of the cap 11 and movably received in the silo 20 for guiding the movement of the cap 11 with respect to the circuit board 40 between the release position and the actuated position. The post 12 comprises opposite sidewalls (not labeled) each having a free end forming a resilient slide tab 13 opposite to each other. The free end of each sidewall also forms two fingers 16 on opposite sides of each slide tab 13 and a cross bar 17 connects and straddles between the fingers 16 and located outboard the slide tab 13 to serve as a stop which will be further described

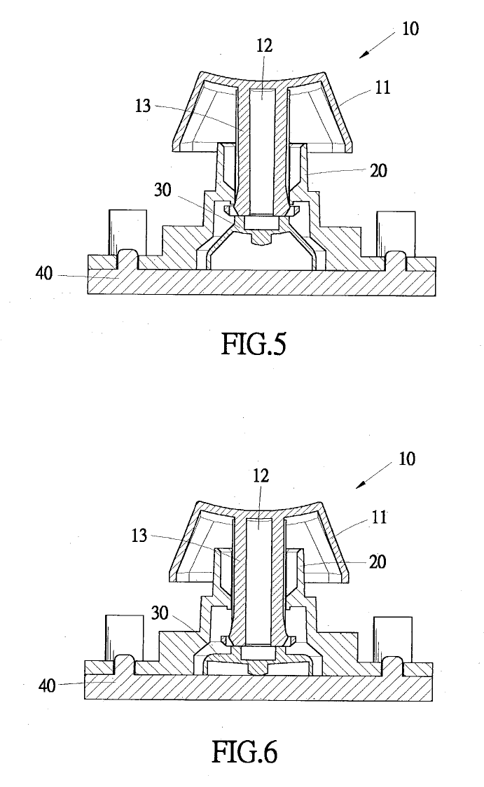

The slide tab 13 forms an outward-projecting wedge-like ridge 14 having at least one inclined face 15. The face 15 extends in a downward and inclined direction which allows for engagement with an inside surface 21 of the silo 20. The resiliency of the slide tab 13 causes a biased engagement between the inclined face 15 and the inside surface 21 of the silo 20, as shown in FIGS. 5 and 6, which ensures stable and sound support of the cap 11 by the silo 20 during the movement of the cap 11 with respect to the silo 20. The resiliency also helps eliminating increased clearance caused by wearing of parts between the cap 11 and the silo 20.

The stop bar 17 that connects between the fingers 16 of the post 12 is located at a position lower than the inclined face 15 of each slide tab 13 whereby the stop bar 17 is engageable with an internal shoulder (not labeled) of the silo 20, as shown in FIG. 5, without interference with the engagement between the slide tab 13 and the inside surface of the silo 20.

Also referring to FIGS. 5 and 6, the post 12 is movably received in the silo 20 with a lower end of the post 12 engaging and supported by the resilient cone 30 as shown in FIG. 5. The engagement between the stop bars 17 and the internal shoulders of the silo 20 maintains the post 12 and the cap 11 at the released position and prevents the cap 11 from separation from the silo 20. When the cap 11 is depressed as shown in FIG. 6, the post 12 is driven toward the circuit board 40 and deforms the resilient cone 30, causing a portion of the cone 30 to physically engage and thus trigger a contact switch (not shown) formed on the circuit board 40. During the movement of the cap 11 and the post 12, the biased engagement between the slide tab 13 and the inside surface 21 of the silo 20 ensures the stability of the movement and thus reducing the noise caused by instable operation of the cap 11.

In addition, since the fingers 16 (as well as the stop bars 17) are arranged on the same sides with the side tabs 13, the overall size of the pushbutton structure 10 can thus be reduced without requiring additional space for the stop bars 17. Further, the amount of material and costs for manufacturing the pushbutton 10 are reduced.

In summary, the pushbutton structure 10 in accordance with the present invention possesses at least the following advantages:

(1) The resilient and biased engagement between the slide tabs 13 and the inside surface 21 of the silo 20 ensures stable and sound movement of the cap 11 with respect to the silo 20, which in turn reduces the noise caused by the movement of the cap 11.

(2) The slide tab 13 and the fingers 16 of the stop bar 17 are formed together without substantial increase of manufacturing costs.

(3) The slide tabs 13, as well as the stop bars 17, are arranged on opposite sides of the post 12 of the cap 11 and are provided with resiliency whereby the manufacturing process of the pushbutton 10 is simple and easy.

(4) The resiliency of the slide tabs 13 helps eliminating increased clearance caused by worn part thereby enhancing reduction of noise.

(5) The slide tabs 13 and the stop bars 17 are arranged at the same sides of the post 12, which helps reducing the overall size of the pushbutton 10 and thus reducing the costs thereof.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. In a keyboard comprising a silo, a pushbutton structure adapted to be movably mounted to the silo comprising:
a post movably received in the silo for movement between a released position and an actuated position;
two resilient slide tabs formed on opposite sides of the post, each slide tab comprising an inclined face for biased engagement with an inside surface of the silo; and
stop means formed on the post and corresponding in position to each slide tab for selective engagement with an internal shoulder of the silo to retain the post at the released position.

2. The pushbutton structure as claimed in claim 1, wherein each slide tab forms an outward-projecting, wedge-like ridge on which the inclined face is formed.

3. The pushbutton structure as claimed in claim 1, wherein the stop means comprises a stop bar mounted to the post by two fingers on opposite sides of the corresponding slide tab, the stop bar engageable with the internal shoulder to retain the post at the released position.

4. A low noise pushbutton structure adapted to be mounted to a silo formed in a keyboard, the pushbutton comprising a cap and a post extending from the cap, the post being movably received in the silo for movement of the cap between released position and actuated position.

5. The low noise pushbutton structure as claimed in claim 4 further comprising two resilient slide tabs formed on opposite sides of the post for resiliency-biased engagement with an inside surface of the silo, stop means being provided on the post for selective engagement with an internal shoulder of the silo to retain the cap at the released position.

6. The low noise pushbutton structure as claimed in claim 5, wherein each slide tab forms an outward-projecting wedge-like ridge to ensure the resiliency-biased engagement between the side tab and the inside surface of the silo.

7. The low noise pushbutton structure as claimed in claim 5, wherein the stop means comprises a stop bar mounted to the post to selectively engage the internal shoulder to retain the post at the released position.

8. The low noise pushbutton structure as claimed in claim 4, wherein the stop means comprises a stop bar mounted to the post by fingers formed on opposite sides of each slide tab to selectively engage the internal shoulder thereby retaining the post at the released position, the stop bar being formed at the same side of the post with the slide tab for reduction of overall size of the post.
